(19) United States
(12) Patent Application Publication
(10) Pub. No.: US 2015/0047430 A1
(43) Pub. Date: Feb. 19, 2015

(54) INTEGRATED HUMIDITY SENSOR AND METHOD FOR THE MANUFACTURE THEREOF

(71) Applicant: Tim Benzel, (US)

(72) Inventor: Hubert Benzel, Pliezhausen (DE)

(21) Appl. No.: 14/350,737

(22) PCT Filed: Oct. 4, 2012
(86) PCT No.: PCT/EP2012/069570

§ 371 Date: Apr. 9, 2014

(30) Foreign Application Priority Data
Nov. 16, 2011 (DE) 10 2011 086 479.2

(51) Int. Cl. G01N 27/22; H01L 21/311; H01L 49/02

(52) U.S. Cl. CPC G01N 27/223; H01L 28/60; H01L 21/311
USPC 73/335.04; 438/49

(57) ABSTRACT

An integrated humidity sensor includes at least one measuring capacitor and one humidity-sensitive polymer as a dielectric that is also suited for use in a dirty, i.e., particle-laden measurement environment. The measuring capacitor of the humidity sensor is in the form of a plate capacitor in the layered structure of the sensor element, the outer of two electrodes being located at the surface of the layered structure. Disposed between the two electrodes of the measuring capacitor is a humidity-sensitive polymer layer that is in direct contact with the measurement environment via humidity-permeable paths in the outer electrode of the measuring capacitor. These humidity-permeable paths extend from the surface of sensor element to the polymer layer, and are so small in lateral extent that they do not significantly affect the electrical conductivity within the outer electrode.

### FIELD OF THE INVENTION

The present invention relates to an integrated humidity sensor that includes at least one measuring capacitor and one humidity-sensitive polymer as a dielectric that is in direct contact with the measurement environment. The present invention also relates to a method for manufacturing an especially advantageous variant of such a humidity sensor.

### BACKGROUND

Humidity sensors are used in air-conditioning systems, for example, which, besides room temperature, also monitor and control air humidity. Improving thermal comfort is not the only purpose of this control. The relative air humidity is also controlled for safety reasons in the passenger compartment of a motor vehicle, for example, namely to prevent or reduce as quickly as possible any fogging of the windows and thereby provide the driver with optimal visibility conditions.

An integrated humidity sensor is known from the field, where measured value acquisition is performed capacitively. The measuring capacitor is realized here in the form of an interdigital capacitor, whose comb-like intermeshing electrodes are configured on the surface of a substrate. A humidity-sensitive polymer layer, which is located above the electrodes on the substrate surface, functions as a dielectric of the measuring capacitor, so that the electrodes of the measuring capacitor are embedded in the humidity-sensitive polymer. The substrate surface, which includes the polymer layer, is exposed to the measurement environment. Since the dielectric properties of the polymer are dependent on the humidity, the humidity of the measurement environment influences the capacitance of the measuring capacitor, allowing inferences to be made about the humidity of the measurement environment based on a change in the capacitance of the measuring capacitor.

### SUMMARY

However, acquiring measured values using the known humidity sensor is a relatively error-prone process. Since the polymer layer is in direct contact with the measurement environment, the deposition of particles, dirt, or liquid droplets from the measurement environment onto the polymer layer cannot be prevented in many applications. Such substances on the polymer layer, regardless of whether they are electrically conductive or dielectric, also influence the electrical field of the measuring capacitor due to the form and configuration of the electrodes and the embedding of the electrodes in the polymer layer. This inevitably leads to a falsification of the measurement signal.

The present invention provides a humidity sensor that is also suited for use in a dirty, i.e., particle-laden, measurement environment.

To this end, the measuring capacitor of the humidity sensor according to the present invention is realized in the form of a plate capacitor in the layered structure of the sensor element, the outer of the two electrodes being located in the surface of the layered structure. A humidity-sensitive polymer layer is disposed between the two electrodes of the plate capacitor. Humidity-permeable paths, which extend from the surface of the sensor element to the polymer layer, are formed in accordance with the present invention in the outer electrode of the measuring capacitor. The humidity-permeable paths are so small in lateral extent, that they do not significantly affect the electrical conductivity within the outer electrode. Thus, the humidity-permeable paths in the outer electrode provide a direct contact for the humidity-sensitive polymer layer of the measuring capacitor with the measurement environment.

In the case of the inventive structure of the sensor element, the outer electrode of the plate capacitor not only functions as a component of the measuring capacitor, but also as a mechanical shield for the humidity-sensitive dielectric against relatively large particles, dirt, and liquid droplets. The present invention recognized, namely, that these types of substances on the outer electrode do not influence the capacitance of the measuring capacitor. However, since the present invention provides that the outer electrode of the measuring capacitor be permeable for the humidity of the measuring environment, and that the dielectric properties of the polymer layer between the two electrodes of the measuring capacitor be dependent on humidity, the measurement signal of the humidity sensor according to the present invention is substantially dependent on the humidity of the measurement environment. At any rate, any possible contamination of the measurement environment does not influence the measurement signal.

In principle, there are different ways to realize the humidity-permeable paths in the outer electrode of the measuring capacitor, as long as the lateral extent thereof is small enough.

Depending on the material and manufacturing process, the humidity-permeable paths may be realized in the form of a porosity, in the form of randomly distributed cracks, or also in the form of a defined patterning of the outer electrode.

The outer electrode is preferably formed in a thin metal layer since there are processes for producing a suitable porosity or also a defined patterning in a metal layer of this kind. Thus, a thin metal layer may be photolithographically patterned, for example. This method is suited, in particular, for producing a defined grid structure in the electrode region.

It is intended that the grid structure preferably extend over the entire surface area of the polymer layer, allowing the humidity, depending on the moisture content of the measurement environment, to penetrate, and be released via the grid openings uniformly and over the entire surface into the polymer layer. Moreover, to achieve the smallest possible diffusion lengths, the width of the grid bars should be smaller or equal to the thickness of the polymer layer. A layout of this kind contributes to the shortening of the response time of the measuring capacitor.

In a manufacturing method according to an example embodiment of the present invention, the humidity-permeable paths in the outer electrode of a humidity sensor, that are formed in a metal layer, are realized in the form of cracks. This merely requires implementation of an annealing step following deposition of the metal layer over the polymer layer. In this process, the polymer layer expands to a significantly greater degree than the superjacent metal layer, causing it to pull apart. The cracks are thereby randomly formed, but are uniformly distributed over the electrode surface. Following cooling, the cracks in the metal layer close up again, humidity-permeable paths remaining in the metal layer, however. Under a suitable annealing temperature, a cohesive metal layer is formed in this manner as an electrode that is electrically conductive and, nevertheless, humidity-permeable. Thus, the method according to the present invention exclusively employs standard processes that may be readily integrated in the overall chip production process.

In any case, the outer electrode of the humidity sensor according to the present invention should be of a most media-resistant possible design since it is configured in the surface of the sensor element and is in direct contact with the measurement environment. To that end, the outer electrode may be provided with a suitable coating, for example. In one example embodiment of the humidity sensor according to the present invention, the outer electrode of the measuring capacitor is realized in a corrosion-resistant metal layer, such as in an Au or Pt layer, for example. In this case, the need for such a coating may be eliminated.

It is noted here that, in principle, the material of the lower electrode may be selected to be independent of the material of the upper electrode. However, it is advantageous that the same material be selected for the upper and lower electrodes to prevent electrolysis-induced corrosion since, upon readout, the two electrodes are at different electric potentials.

In one especially advantageous example embodiment of the present invention, the lower electrode of the measuring capacitor is of a meander-shaped design. Moreover, an arrangement is provided for optionally energizing the lower electrode. In this example embodiment, a current for heating the polymer layer may be conducted through the meander-shaped electrode in order to accelerate the release of moisture from the polymer. The humidity sensor's response time may be significantly reduced in this manner.

In any case, according to example embodiments of the present invention, the outer electrode of the measuring capacitor is preferably connected to ground potential since, in this manner, an electrolytic destruction of the measuring capacitor in an aggressive measurement environment may be prevented.

One advantageous example embodiment of the humidity sensor according to the present invention provides that, in addition to the measuring capacitor, in the layered structure of the sensor element, at least one reference capacitor is provided whose design essentially corresponds to that of the measuring capacitor. However, in contrast to the measuring capacitor, the outer electrode of the reference capacitor does not include any humidity-permeable paths, so that humidity is not able to penetrate here into the humidity-sensitive polymer layer. Accordingly, the capacitance of the reference capacitor is humidity-independent. An appropriate evaluation circuit may be used to analyze the difference between the signals of the measuring capacitor and the reference capacitor. This makes it possible to not only reduce the influence of material parameters of the capacitors on the sensor signal, but also the influence of disturbance parameters, such as the temperature effects arising from the thermal expansion of the polymer, or the influence of long-term drifts which occur simultaneously in both capacitors.

To prevent an electrolytic destruction of the electrodes in this case as well, according to an example embodiment, the outer electrodes of the measuring capacitor and of the reference capacitor are connected to ground potential, since both certainly come in contact with the measuring medium.

In one especially space-saving example embodiment of the humidity sensor according to the present invention, at least parts of an evaluation circuit for the measuring capacitor are integrated in the layered structure underneath the measuring capacitor. Since the measuring capacitor is realized as a plate capacitor in accordance with the present invention, the electrical field of the measuring capacitor is not thereby influenced.

The teaching of the present invention may be advantageously embodied and further refined in various ways. The following is a description of two example embodiments of the present invention, with reference to the figures.

### BRIEF DESCRIPTION OF THE DRAWINGS

FIGS. 1a-1c each shows a section through the layered structure of a humidity sensor 10 according to an example embodiment of the present invention, in successive stages of the manufacture thereof.

FIG. 2 shows a section through humidity sensor 10 in accordance with an optional manufacturing step for shortening the diffusion paths in the polymer layer, according to an example embodiment of the present invention.

FIG. 3 shows a section through humidity sensor 10 including the molded housing, according to an example embodiment of the present invention.

FIG. 4 shows a section through a humidity sensor 40 including a measuring capacitor and a reference capacitor.

### DETAILED DESCRIPTION

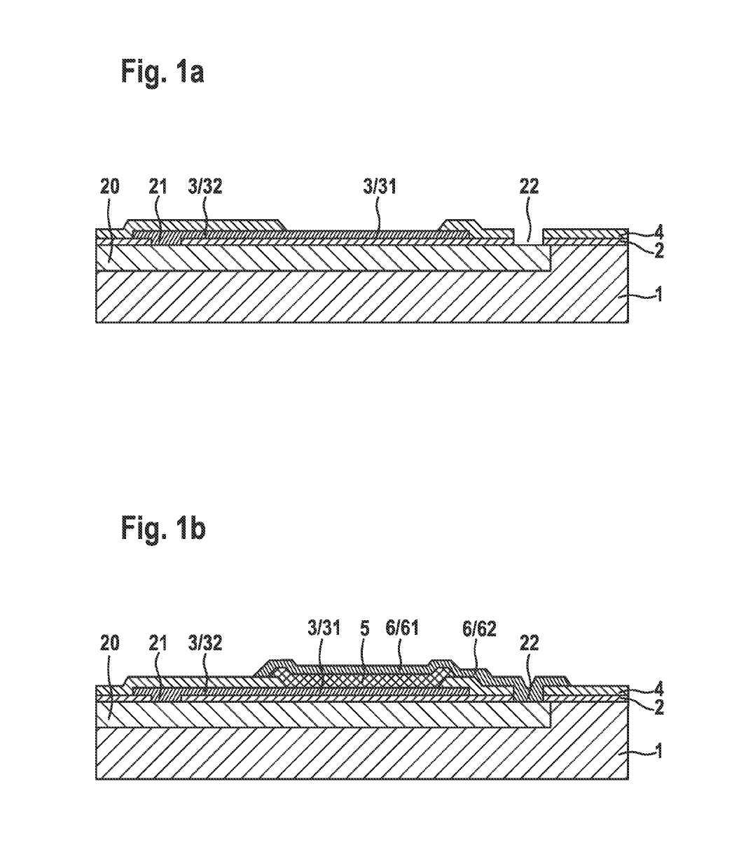

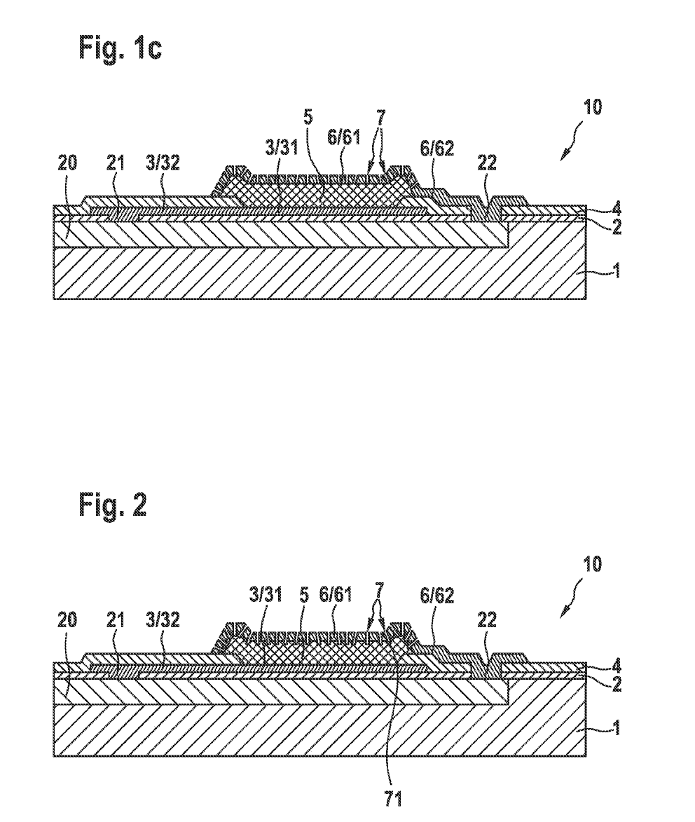

The design of humidity sensor 10 shown in FIG. 1c is the result of a manufacturing process that is explained in the following with reference to FIGS. 1a-1c. The starting point of this manufacturing process is a semiconductor substrate 1 that has been equipped with a microelectromechanical systems (MEMS) functionality in the course of a preprocessing. The MEMS functionality is merely shown schematically here and is denoted by 20, and may include parts of an evaluation circuit, for example, that are integrated in the substrate surface.

The sensor function of humidity sensor 10 is realized here in a layered structure on the substrate surface and as a function of MEMS functionality 20. To this end, the substrate surface is first provided with an electrically insulating oxide layer 2, which, in the course of a patterning process, is merely open in connecting regions 21 and 22 for electrically contacting evaluation circuit 20. Deposited onto patterned oxide layer 2 is a metal layer 3 that functions as first electrode layer. The metal layer may be formed of Al, AlSiCu, AlCu, Au, Pt, or a similar material, for example. Patterned from this metal layer 3 is first, lower electrode 31 of a measuring capacitor, as well as a connecting lead 32 to connecting region 21, where electrode 31 is connected to evaluation circuit 20. A passivation layer 4 is then deposited on the layered structure. It may be a nitride or an oxynitride layer, for example. This passivation layer 4 is also patterned. Passivation layer 4 is open in electrode region 31 and in connecting region 22. This situation is illustrated in FIG. 1a.

Referring to FIG. 1b, a humidity-sensitive polymer layer 5 is deposited onto the layered structure and patterned in such a way that polymer layer 5 essentially remains only in electrode region 31, but completely covers the same. Deposited thereover is a second electrode layer in the form of a thin metal layer 6. Second, outer electrode 61 of the measuring capacitor, as well as a connecting lead 62 are patterned from this metal layer 6. Since outer electrode 61 is exposed to the humid measurement environment, the use of a corrosion-resistant metal, such as Au or Pt, for example, is recommended. The patterning of a metal layer of this kind may be simply carried out in an etching process with the aid of a photolithographically produced masking. Via connecting region 22, connecting lead 62 establishes an electrical connection between outer electrode 61 and evaluation circuit 20. FIG. 1b shows that outer electrode 6 extends to beyond the edge of, and therefore completely covers, polymer layer 5. In this edge region, outer electrode 6 is electrically insulated by passivation layer 4 from lower electrode 3.

In accordance with the claimed manufacturing method, substrate 1 with the layered structure undergoes an annealing step. In the process, polymer layer 5 expands to a significantly greater degree than superjacent metal layer 6 of outer electrode 61, so that cracks 7 form in entire electrode region 61 over polymer layer 5, as illustrated in FIG. 1c. However, due to the lower thermal expansion of passivation layer 4, metal layer 6 does not tears apart in the edge region of electrode 61 and does not tear apart in the region of connecting lead 62, thereby ensuring a reliable electrical connection of outer electrode 61 to evaluation circuit 20. Following cooling, cracks 7 close up substantially again. All that remain are humidity-permeable paths 7 in outer electrode 61, so that these are continuous and electrically conductive, but, nevertheless, humidity-permeable.

The manufacturing method described above may also be supplemented by a polymer etching step, where the material of polymer layer 5 is easily ablated through open cracks 7. This is achieved, for example, by the short-term addition of oxygen plasma during the annealing process. The result of such a polymer etching step is shown in FIG. 2. Hollow spaces, respectively depressions 71, formed in polymer layer 5 during the process, shorten the diffusion paths within polymer layer 5. Employing this measure makes it possible to shorten the response time of humidity sensor 10 according to the present invention.

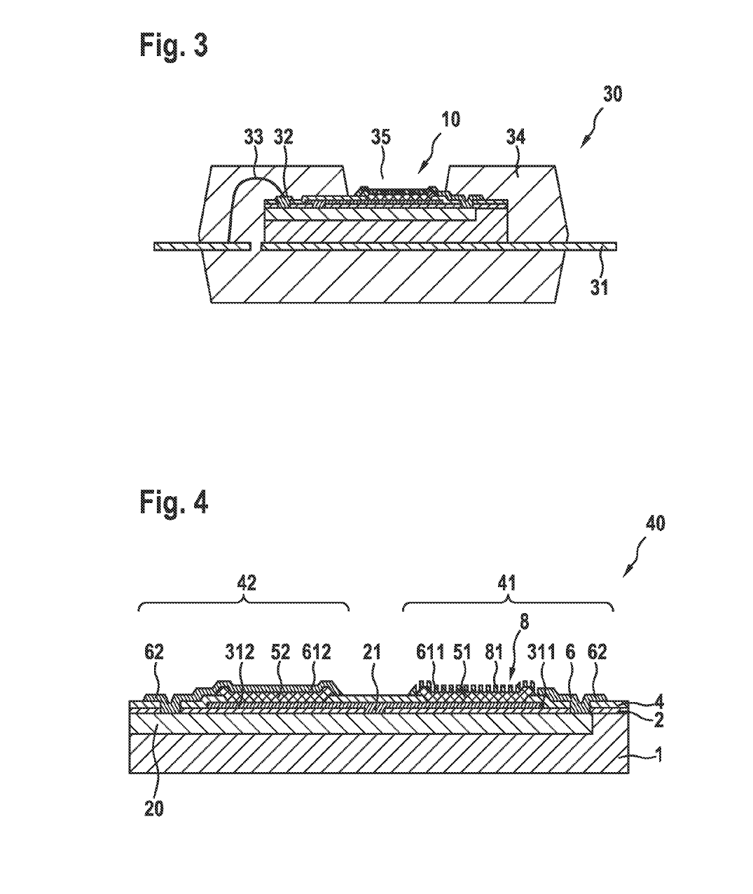

Prior to installation on site, humidity sensor 10 is also provided with a packaging. This may be a molded housing 30, for example, as shown in FIG. 3. To this end, humidity sensor 10 is first mounted on a leadframe 31 and electrically contacted via a bonding connection 32 by bonding wires 33. Entire sensor element 10, together with leadframe 31 and bonding connection 32, 33, is then embedded in a molding compound 34. As a connection to the measurement environment, molded housing 30 features an access opening 35 merely in the area of outer electrode 61. This type of packaging is very cost-effective and may be manufactured using standard molding tools.

Humidity sensor 40 illustrated in FIG. 4 includes a measuring capacitor 41 and a reference capacitor 42. The two capacitors 41 and 42 are configured side-by-side and over an evaluation circuit 20 that is integrated in substrate 1 of humidity sensor 40. The layered structure of humidity sensor 40 essentially corresponds to that of humidity sensor 10 illustrated in FIGS. 1 and 2 and includes a patterned oxide layer 2 on the substrate surface as an electrical insulation between substrate 1, including evaluation circuit 20, and capacitors 41 and 42. Disposed above layer 2 is a patterned metal layer 3 as a first electrode layer in which both lower electrode 311 of measuring capacitor 41, as well as lower electrode 312 of reference capacitor 42, along with corresponding connecting leads 32, are configured. These two lower electrodes 311 and 312 are designed to be mutually congruent and are connected in the example embodiment shown here via a common middle connection 21 to evaluation circuit 20. Located above first electrode layer 3 is a patterned passivation layer 4 that is open over two bottom electrodes 311 and 312. A humidity-sensitive polymer layer 51, 52, respectively, completely covers these two electrode regions 311 and 312, but is limited to approximately these two respective regions 311 and 312. Disposed above layer 51, 52 is a second patterned metal layer 6 as a second electrode layer. Configured in this metal layer 6 are two outer electrodes 611 and 612 of measuring capacitor 41 and of reference capacitor 42, along with corresponding connecting leads 62. Similar to the case of two lower electrodes 311 and 312, the electrode surfaces are essentially identical in the case of the two outer electrodes 611 and 612 as well, so that the design of measuring capacitor 41 and reference capacitor 42 is the same, except for the sole distinction between the two capacitors 41 and 42 that humidity-permeable paths 8 are realized in outer electrode 611 of the measuring capacitor, while outer electrode 612 of reference capacitor 42 is unpatterned, thus forming a closed, humidity-impermeable surface.

As already mentioned, in the variant illustrated here, two lower electrodes 311 and 312 are interconnected via common middle connection 21 and, accordingly, are connected to ground potential. However, particularly when such a humidity sensor is used in an aggressive measurement environment, it proves to be advantageous when the measuring capacitor and the reference capacitor include a common cover electrode, i.e., the outer electrodes are connected by the measuring and reference capacitor and are connected to ground potential. As a result, no electrolysis takes place, even in the case of condensation of the electrodes on the sensor surface. Moreover, a configuration of this kind is also shielded from external radiation (EMC). To realize humidity-permeable paths 8, outer electrode 611 of measuring capacitor 41 is provided with a grid structure in the course of pattering metal layer 6. In the process, small, grid-arrayed openings 8 are etched into metal layer 6 with the aid of a photolithographically patterned mask. To this end, a hard mask may also be used that is composed of an oxide or nitride layer, for example, and subsequently remains as a passivation layer on the surface of sensor element 40. The width of grid bars 81 is selected here to be smaller than the thickness of polymer layer 51. FIG. 4 illustrates that the grid structure extends to the edge of polymer layer 51, thereby allowing the humidity of the measuring environment to act uniformly on the entire surface of polymer layer 51 of measuring capacitor 41.

While the humidity of the measurement environment penetrates through the grid structure of outer electrode 611 to humidity-sensitive polymer layer 51 of measuring capacitor 41, polymer layer 52 of reference capacitor 42, including outer electrode 612, remains unaffected therefrom. Accordingly, the capacitance of reference capacitor 42 is independent of the humidity of the measurement environment. By performing difference, quotient operations on the signals of measuring capacitor 41 and of reference capacitor 42, it is now possible to generate a sensor signal that is purged of interference effects that occur in equal measure on both capacitors 41 and 42, such as by the influence of material parameters, temperature effects arising from the thermal expansion of the polymer, and long-term drifts, for example.

1-11. (canceled)

12. An integrated humidity sensor of layered structure configured for measuring humidity in a measurement environment, the sensor comprising:
a measuring plate capacitor in layers of the sensor, the measuring plate capacitor including:
an upper electrode at a surface of the layered structure;
a lower electrode;
a dielectric humidity-sensitive polymer layer that is disposed between the upper and lower electrodes and that is in direct contact with the measurement environment; and
a passivation layer that is located between an edge region of the upper electrode and the lower electrode and that electrically insulates the upper and lower electrodes from each other;
wherein the upper electrode includes humidity-permeable paths (a) that extend from the surface of the layered structure to the polymer layer, and (b) whose widths are small enough such that they do not significantly affect electrical conductivity within the upper electrode.

13. The humidity sensor of claim 12, wherein a thermal expansion coefficient of the passivation layer is smaller than that of the polymer layer.

14. The humidity sensor of claim 12, wherein the humidity-permeable paths are provided by at least one of (a) a porosity of the upper electrode, (b) randomly distributed cracks in the upper electrode, and (c) a defined patterning in the upper electrode.

15. The humidity sensor of claim 12, wherein the humidity-permeable paths are in the form of a grid structure of grid bars in the upper electrode, the width of the grid bars being smaller or equal to the thickness of the polymer layer.

16. The humidity sensor of claim 12, wherein the upper electrode is a corrosion-resistant metal layer.

17. The humidity sensor of claim 12, wherein the lower electrode is meander-shaped, and the humidity sensor further includes an energizing component arranged for energizing the lower electrode.

18. The humidity sensor of claim 12, wherein the upper electrode is connected to ground potential.

19. The humidity sensor of claim 12, further comprising:
a reference capacitor including upper and lower electrodes and a dielectric polymer layer, wherein the upper electrode of the reference capacitor does not include any humidity-permeable paths.

20. The humidity sensor of claim 19, wherein the upper electrodes of the measuring capacitor and of the reference capacitor are interconnected and are connected to ground potential.

21. The humidity sensor of claim 12, wherein, except for the lack of humidity-permeable paths in the upper electrode of the reference capacitor, the measuring and reference capacitors are identical.

22. The humidity sensor of claim 12, further comprising an evaluation circuit, at least parts of which are integrated in the layered structure underneath the measuring plate capacitor.

23. A method for manufacturing an integrated humidity sensor, the method comprising:
forming a lower electrode of a measuring capacitor in a first electrode layer over a semiconductor substrate;
depositing a passivation layer on the first electrode layer, the passivation layer being patterned with an opening in a region of the lower electrode;
depositing a humidity-sensitive polymer layer over the lower electrode;
depositing onto the polymer layer a thin metal layer as a second electrode layer including an upper electrode of the measuring capacitor; and
producing, in the upper electrode, humidity-permeable cracks (a) that extend through an entire thickness of the thin metal layer to the polymer layer, and (b) whose widths are small enough such that they do not significantly affect electrical conductivity within the upper electrode.

24. The method of claim 23, further comprising:
etching the polymer layer via the cracks, thereby forming depressions in the polymer layer at an outlet region of the cracks.
